(19) United States
(12) Patent Application Publication
(10) Pub. No.: US 2022/0085103 A1
(43) Pub. Date: Mar. 17, 2022

(54) MAGNETIC MEMORY DEVICE AND METHOD FOR MANUFACTURING THE SAME

(71) Applicant: Kioxia Corporation, Minato-ku (JP)

(72) Inventors: Kenichi YOSHINO, Seongnam-si Gyeonggi-do (KR); Eiji KITAGAWA, Seoul (KR); Naoki AKIYAMA, Seoul (KR)

(73) Assignee: Kioxia Corporation, Minato-ku (JP)

(21) Appl. No.: 17/199,593

(22) Filed: Mar. 12, 2021

(30) Foreign Application Priority Data
Sep. 17, 2020 (JP) 2020-156160

(51) Int. Cl. H01L 27/22; H01L 43/02; H01L 43/12

(52) U.S. Cl. CPC H01L 27/224; H01L 43/12; H01L 43/02

(57) ABSTRACT

According to one embodiment, a magnetic memory device includes: a first interconnect extending in a first direction; a switching element provided on the first interconnect; a conductor provided on the switching element; a magnetoresistance effect element provided on the conductor; and an insulating layer provided in a layer in which the switching element is provided. An area of a first principal surface of the switching element that faces the conductor is smaller than that of a second principal surface of the conductor that faces the switching element.

### CROSS-REFERENCE TO RELATED APPLICATIONS

This application is based upon and claims the benefit of priority from Japanese Patent Application No. 2020-156160, filed Sep. 17, 2020, the entire contents of which are incorporated herein by reference.

### FIELD

Embodiments described herein relate generally to a magnetic memory device and a method for manufacturing the same.

### BACKGROUND

A magnetic memory device (Magnetoresistive Random Access Memory (MRAM)) which adopts a magnetoresistance effect element as a memory element is known.

### BRIEF DESCRIPTION OF THE DRAWINGS

FIG. 1 is a block diagram of a magnetic memory device according to a first embodiment.

FIG. 2 is a circuit diagram of a memory cell array included in the magnetic memory device according to the first embodiment.

FIG. 3 is a cross-sectional view of the memory cell array included in the magnetic memory device according to the first embodiment.

FIG. 4 is a plan view of middle electrodes in the memory cell array included in the magnetic memory device according to the first embodiment.

FIG. 5 is a cross-sectional view of a magnetoresistance effect element included in the magnetic memory device according to the first embodiment.

FIG. 6 is a flowchart showing a process of manufacturing the memory cell array included in the magnetic memory device according to the first embodiment.

FIGS. 7 to 14 are cross-sectional views showing a process of manufacturing the memory cell array included in the magnetic memory device according to the first embodiment.

FIG. 15 is a cross-sectional view of a memory cell array included in a magnetic memory device according to a second embodiment.

FIG. 16 is a flowchart showing a process of manufacturing the memory cell array included in the magnetic memory device according to the second embodiment.

FIGS. 17 to 19 are cross-sectional views showing a process of manufacturing the memory cell array included in the magnetic memory device according to the second embodiment.

### DETAILED DESCRIPTION

In general, according to one embodiment, a magnetic memory device comprising: a first interconnect extending in a first direction; a switching element provided on the first interconnect; a conductor provided on the switching element; a magnetoresistance effect element provided on the conductor; and an insulating layer provided in a layer in which the switching element is provided. An area of a first principal surface of the switching element that faces the conductor is smaller than that of a second principal surface of the switching element that faces the conductor.

Hereinafter, embodiments will be explained with reference to the accompanying drawings. In the following explanation, structural components having the same functions and configurations will be referred to by the same reference symbol. In case structural components having the same reference symbols need to be distinguished from each other, letters or numerals may be added to the symbols. If the structural components need not be distinguished particularly from each other, only the common reference symbols are used, without additional letters or numerals. The additional letters or numerals are not limited to a superscript or subscript, but may be lower-case alphabetic characters attached to the end of a reference symbol, and indices indicating the arrangement order.

### 1. First Embodiment

A magnetic memory device according to the first embodiment will be explained. The magnetic memory device according to the first embodiment is, for example, a perpendicular magnetization-type magnetic memory device in which an element having a magnetoresistive effect provided by a magnetic tunnel junction (MTJ) (such an element may be called an MTJ element) as a resistance change element.

In the present embodiment and a second embodiment described later, a case is explained in which an MTJ element is used as a resistance change element, which is referred to as a magnetoresistance effect element MTJ.

1.1 Configuration

First, a configuration of a magnetic memory device according to the first embodiment will be explained.

1.1.1 Configuration of Magnetic Memory Device

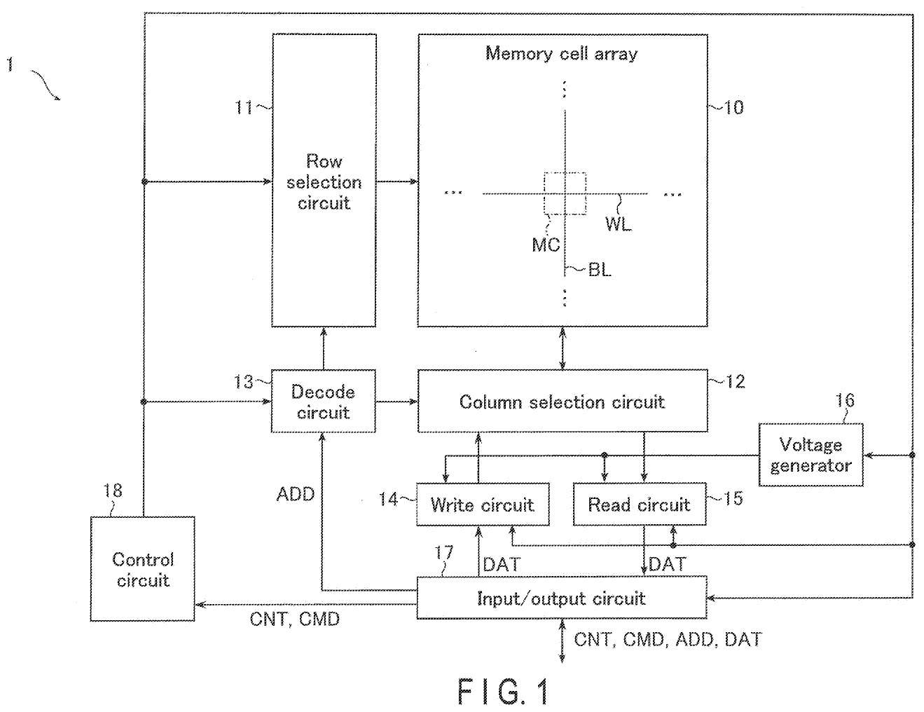

FIG. 1 is a block diagram showing an example of a configuration of the magnetic memory device according to the first embodiment. As illustrated in FIG. 1, the magnetic memory device 1 includes a memory cell array 10, a row selection circuit 11, a column selection circuit 12, a decode circuit 13, a write circuit 14, a read circuit 15, a voltage generator 16, an input/output circuit 17, and a control circuit 18.

The memory cell array 10 includes a plurality of memory cells MC, each of which is associated with a pair of one row and one column. Specifically, the memory cells MC of the same row are coupled to the same word line WL, and the memory cells MC of the same column are coupled to the same bit line BL.

The row selection circuit 11 is coupled to the memory cell array 10 by way of word lines WL. The row selection circuit 11 receives decoding results (row address) of an address ADD from the decode circuit 13. The row selection circuit 11 sets a word line WL corresponding to the row address to a selected state. Hereinafter, a word line WL set to a selected state will be referred to as a selected word line WL. Word lines WL other than the selected word line WL will be referred to as non-selected word lines WL.

The column selection circuit 12 is coupled to the memory cell array 10 by way of bit lines BL. The column selection circuit 12 receives decoding results (column address) of the address ADD from the decode circuit 13. The column selection circuit 12 sets a bit line BL corresponding to the column address to a selected state. Hereinafter, a bit line BL set to a selected state will be referred to as a selected bit line BL. Bit lines BL other than the selected bit line BL will be referred to as non-selected bit lines BL.

The decode circuit 13 decodes the address ADD received from the input/output circuit 17. The decode circuit 13 supplies the decoding results of the address ADD to the row selection circuit 11 and the column selection circuit 12. The address ADD includes a column address and a row address.

The write circuit 14 writes data to memory cells MC. The write circuit 14 includes, for example, a write driver (not shown).

The read circuit 15 reads data from memory cells MC. The read circuit 15 includes, for example, a sense amplifier (not shown).

The voltage generator 16 generates voltages for various types of operations of the memory cell array 10, using a power supply voltage provided from an outside (not illustrated) of the magnetic memory device 1. The voltage generator 16 generates, for example, a variety of voltages necessary for a write operation, and outputs the generated voltages to the write circuit 14. Also, the voltage generator 16 generates, for example, a variety of voltages necessary for a read operation, and outputs the generated voltages to the read circuit 15.

The input/output circuit 17 transfers an address ADD received from the outside of the magnetic memory device 1, to the decode circuit 13. The input/output circuit 17 transfers a command CMD received from the outside of the magnetic storage device 1, to the control circuit 18. The input/output circuit 17 transmits and receives various control signals CNT between the outside of the magnetic storage device 1 and the control circuit 18. The input/output circuit 17 transfers to the write circuit 14 the data DAT received from the outside of the magnetic memory device 1, and outputs to the outside of the magnetic memory device 1 the data DAT transferred from the read circuit 15.

The control circuit 18 controls the operations of the row selection circuit 11, the column selection circuit 12, the decode circuit 13, the write circuit 14, the read circuit 15, the voltage generator 16, and the input/output circuit 17 in the magnetic storage device 1 in accordance with the control signal CNT and command CMD.

1.1.2 Circuit Configuration of Memory Cell Array

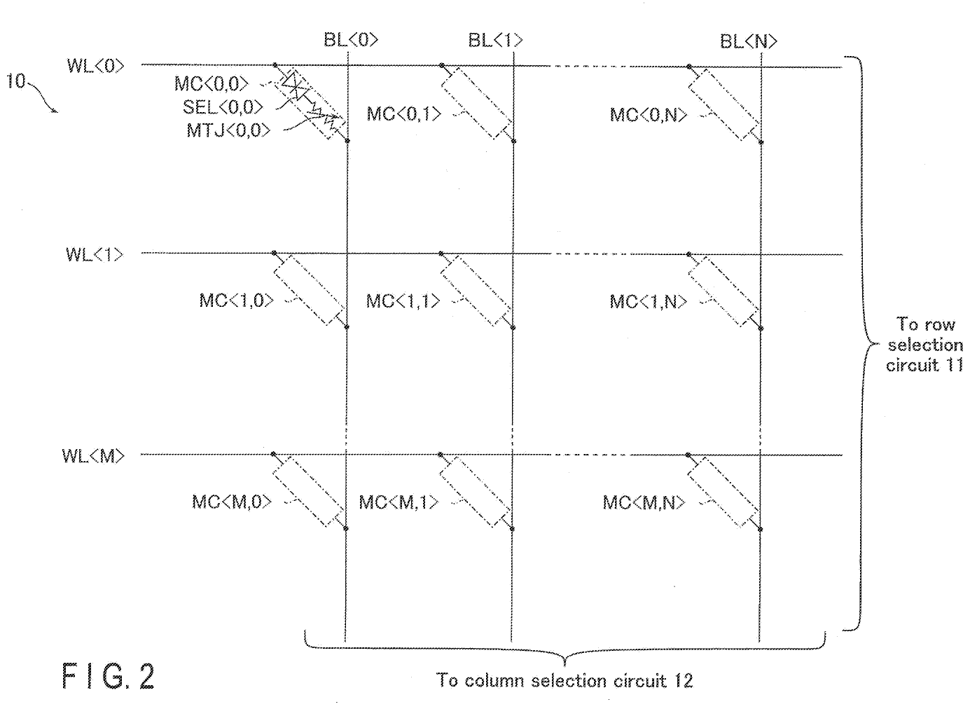

Next, an example configuration of the memory cell array 10 will be explained with reference to FIG. 2. FIG. 2 is a circuit diagram showing a configuration of the memory cell array 10. In the example of FIG. 2, the word lines WL are classified by additional letters or numerals including indices (“< >”).

As illustrated in FIG. 2, the memory cells MC are arranged in a matrix in the memory cell array 10, and each memory cell is associated with a pair of one of the bit lines BL (BL<0>, BL<1>, . . . , BL<N>) and one of the word lines WL (WL<0>, WL<1>, . . . , WL<M>) (where M and N are integers). In other words, a memory cell MC<i, j> (0≤i ≤M, 0≤j≤N) is coupled between a word line WL<i> and a bit line BL<j>.

The memory cell MC<i, j> includes a selector SEL<i, j> and a magnetoresistance effect element MTJ<i, j> coupled in series thereto. More specifically, one end of the selector SEL<i, j> is coupled to one word line WL<i> and the other end thereof is coupled to one end of the magnetoresistance effect element MTJ<i, j>. The other end of the magnetoresistance effect element MTJ<i, j> is coupled to one single bit line BL<j>.

The selector SEL (also referred to as the switching element) has a function as a switch that controls a supply of a current to a corresponding magnetoresistance effect element MTJ in a read operation and a write operation with respect to the magnetoresistance effect element MT-T. More specifically, the selector SEL in a memory cell MC, for example, serves as an insulator having a large resistance value and cuts off a current (in other words, is in an off state) when a voltage applied to the memory cell MC is lower than a threshold voltage, and serves as a conductor having a small resistance value and allows a current to flow (in other words, is in an on state) when the voltage is equal to or higher than the threshold voltage. In other words, the switching element SEL has a function of switching between interruption and passing of the current, in accordance with the voltage applied to the memory cell MC, regardless of the direction of the current flow.

The selector SEL may be, for example, a two-terminal type switching element. When the voltage applied between the two terminals is lower than the threshold voltage, this switching element is in a “high resistance” state, for example, in an electrically non-conductive state. When the voltage applied between the two terminals is equal to or higher than the threshold voltage, the switching element is in a “low resistance” state, for example, in an electrically conductive state. The switching element may have this function regardless of the polarity of the voltage.

With the current supply controlled by the switching element SEL, the resistance value of the magnetoresistance effect element MTJ can be switched between the low resistance state and high resistance state. The magnetoresistance effect element MTJ is designed to be data-writable in accordance with the change of the resistance state of the element, and stores written data in a non-volatile manner to function as a readable memory element.

1.1.3 Configuration of Memory Cell Array

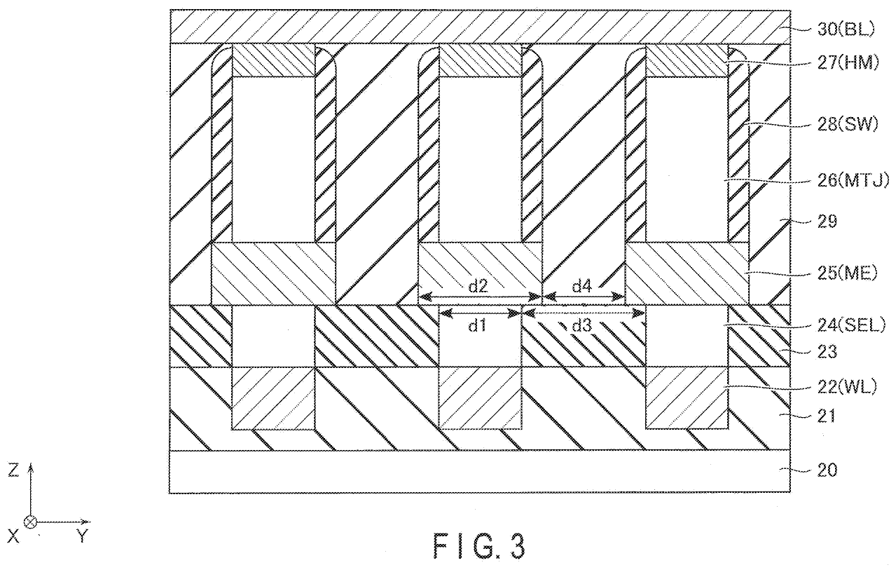

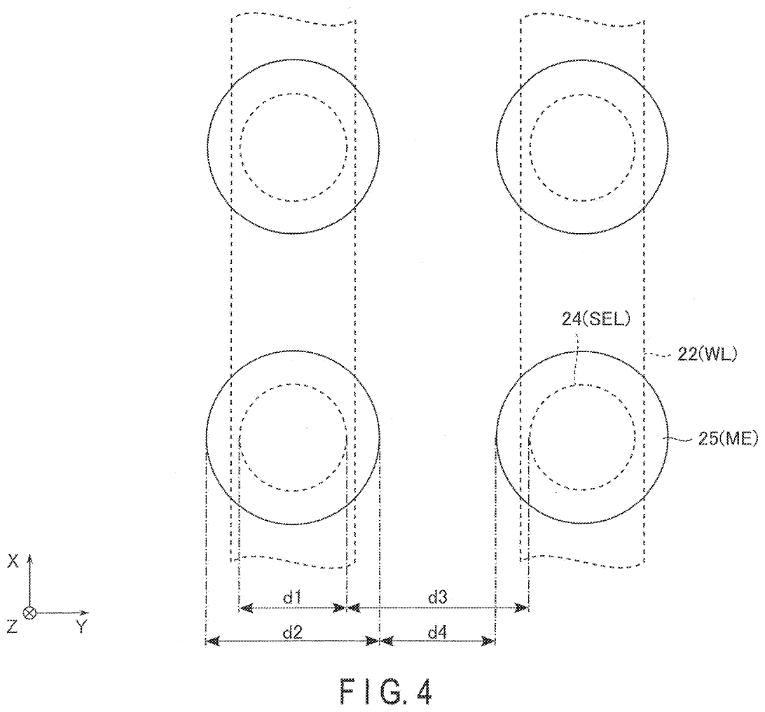

Next, an example configuration of the memory cell array 10 will be explained with reference to FIG. 3 and FIG. 4. In the following description, a plane parallel to the surface of a semiconductor substrate 20 is defined as an XY plane, and a direction perpendicular to the XY plane is defined as a Z direction. On the XY plane, the direction along the word lines WL is defined as an X direction, and the direction along the bit lines BL is defined as a Y direction. In each structural component, a surface that faces the semiconductor substrate in the Z direction is defined as a lower surface, and a surface opposing the lower surface is defined as an upper surface. FIG. 3 is a cross-sectional view of the memory cell array 10 along the Y direction. FIG. 4 is a plan view showing middle electrodes ME (conductor 25) on the XY plane.

As illustrated in FIG. 3, an insulating layer 21 is provided on the semiconductor substrate 20. In an upper region in the insulating layer 21, a plurality of interconnect layers 22 extending in the X direction and functioning as the word lines WL are provided. The interconnect layers 22 are formed of a conductive material. The interconnect layers 22 may be formed on the upper surface of the semiconductor substrate 20.

An insulating layer 23 is provided on the insulating layer 21. More specifically, the insulating layer 23 is provided between a plurality of elements 24, namely, provided in the same layer as the elements 24. The insulating layer 23 is formed of, for example, SiO₂.

On the interconnect layers 22, the elements 24 functioning as the selectors SEL are provided. One element 24 corresponds to the selector SEL of one memory cell MC. For example, the elements 24 are arranged in a matrix in the X direction and the Y direction on the XY plane. The elements 24 that are arranged in the X direction are located on the upper surface of one interconnect layer 22. An electrode may be provided between and electrically couple the interconnect layer 22 and the element 24. The element 24 is formed of a material including an insulator, and contains a dopant introduced by ion implantation. The insulator contains, for example, an oxide, such as SiO₂ or a material substantially formed of SiO₂. The dopant contains, for example, arsenic (As) or germanium (Ge).

The element 24 may have a substantially pillar shape, for example. The substantially pillar shape includes a shape having an upper or bottom surface of a perfect circle or an almost perfect circle. The shape of the element 24 is not limited to a pillar shape. The shape of the element 24 depends on, for example, a profile of the dopant. Therefore, the element 24 may be, for example, a circular truncated cone. Furthermore, the upper surface of the element 24 may be a rectangle. To simplify the description, a case will be described below where the element 24 has a pillar shape.

The element 24 is formed by implanting the dopant into the insulating layer 23. Thus, the element 24 is formed without a process of dry etching or the like. Therefore, an interface between the insulating layer 23 and the element 24 cannot be observed with a transmission electron microscope (TEM). However, the element 24 can be recognized by measuring a distribution of the dopant by energy dispersive X-ray spectroscopy (EDX) analysis with the TEM.

A conductor 25 functioning as a middle electrode (ME) between the selector SEL (element 24) and the magnetoresistance effect element MTJ (element 26) is provided on the upper surface of the element 24. The conductor 25 is formed of a conductive material and contains, for example, titanium nitride (TiN).

The element 26 functioning as the magnetoresistance effect elements MTJ is provided on the upper surface of the conductor 25. The element 26 may have a substantially pillar shape, for example. The shape of the element 26 is not limited to a pillar shape. For example, the element 26 may have a tapered side surface depending on the etching characteristic when the element 26 is processed. In such a case, the element 26 may be, for example, a circular truncated cone. Furthermore, the upper surface of the element 26 may be a rectangle. To simplify the description, a case will be described below where the element 26 has a pillar shape. The details of the configuration of the element 26 will be described later.

A hard mask 27 is provided on the upper surface of the element 26. The hard mask 27 functions as a hard mask used when the element 26 is processed. The hard mask 27 is formed of a conductive material and contains, for example, TiN.

An insulator 28 is provided on side surfaces of the element 26 and the hard mask 27. The insulator 28 functions as a protecting film, namely, a side wall SW, to protect the element 26 when the conductor 25 is processed. The insulator 28 provided on the side surfaces of the pillar-shaped element 26 and the hard mask 27 has a cylindrical shape. The insulator 28 is formed of an insulating material, for example, silicon nitride (SiN).

The conductor 25 is processed using the hard mask 27 and the insulator 28 as a hard mask. Therefore, the peripheral shape of the upper surface of the conductor 25 and the peripheral shape of the insulator 28 are almost the same. The expression “almost the same” may include an error that occurs in the manufacturing process, for example, a difference in etching rate due to a difference in materials, etc. Accordingly, the upper surface of the conductor 25 has a circular shape according to the present embodiment. To simplify the description, a case will be described below where the conductor 25 has a pillar shape. The shape of the conductor 25, however, is not limited to a pillar shape. The shape of the conductor 25 may be, for example, a circular truncated cone.

An insulating layer 29 is provided on the upper surface of the insulating layer 23. The insulating layer 29 is formed of, for example, SiO₂.

The upper surface of each hard mask 27 is coupled to the lower surface of any of a plurality of interconnect layers 30 extending in the Y direction. More specifically, the hard masks 27 (in other words, the elements 26) arranged in the Y direction are coupled to one interconnect layer 30. The interconnect layer 30 functions as a bit line BL. The interconnect layer 30 is formed of a conductive material and contains, for example, tungsten (W). An electrode may be provided between and electrically couple the hard mask 27 and the interconnect layer 30.

As illustrated in FIG. 4, in the present embodiment, if the upper surface of the element 24 has a substantially circular shape, the longest diameter (hereinafter referred to as “the major axis”) is defined as d1. If the lower surface of the conductor 25 that faces the element 24 has a substantially circular shape, the major axis is defined as d2. In this case, d1 and d2 satisfy the relation of d1<d2. In other words, according to the present embodiment, the area of the upper surface of the element 24 (the surface facing the conductor 25) is smaller than the area of the lower surface of the conductor 25 (the surface facing the element 24). The distance between the upper surfaces of the adjacent elements 24 is defined as d3, and the distance between the lower surfaces of the adjacent conductors 25 is defined as d4. In this case, the distances d3 and d4 satisfy the relation of d3>d4. The shape of the upper surface of the element 24 and the shape of the lower surface of the adjacent conductor 25 need not be the same. For example, either one of the upper surface of the element 24 or the lower surface of the conductor 25 may be circular, while the other may be rectangular.

In the embodiment described above, the magnetoresistance effect elements MTJ and the bit lines BL are arranged above the word lines WL. However, the arrangement is not limited to this. For example, the magnetoresistance effect elements MTJ and the word line WL may be arranged above the bit lines BL. In this case, the interconnect layers 22 function as bit lines BL, and the interconnect layers 30 function as word lines WL.

1.1.4 Configuration of Magnetoresistance Effect Element

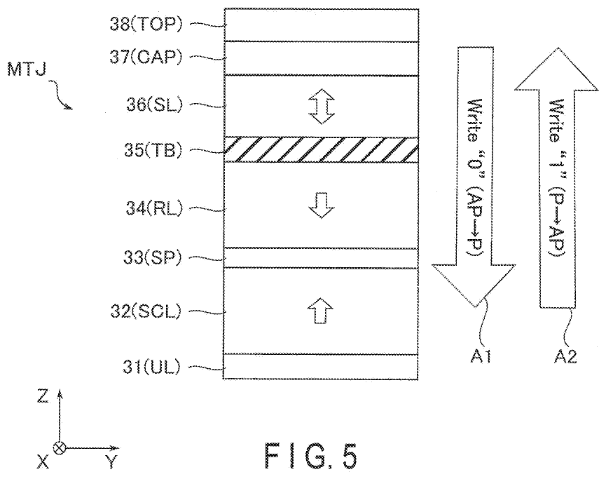

Next, an example of a configuration of a magnetoresistance effect element MTJ will be explained with reference to FIG. 5. FIG. 5 is a cross-sectional view showing a configuration of the element 26, namely, the magnetoresistance effect element MTJ.

As illustrated in FIG. 5, the magnetoresistance effect element MTJ includes, for example, a nonmagnet 31 which functions as an under layer UL, a ferromagnet 32 which functions as a shift cancelling layer SCL, a nonmagnet 33 which functions as a spacer layer SP, a ferromagnet 34 which functions as a reference layer RL, a nonmagnet 35 which functions as a tunnel barrier layer TB, a ferromagnet 36 which functions as a storage layer SL, a nonmagnet 37 which functions as a capping layer CAP, and a nonmagnet 38 which functions as a top layer TOP.

In the magnetoresistance effect element MTJ, the nonmagnet 31, the ferromagnet 32, the nonmagnet 33, the ferromagnet 34, the nonmagnet 35, the ferromagnet 36, the nonmagnet 37, and the nonmagnet 38 are stacked in this order, from the side of the word line WL (the interconnect layer 22) toward the side of the bit line BL (the interconnect layer 30). Alternatively, the nonmagnet 38, the nonmagnet 37, the ferromagnet 36, the nonmagnet 35, the ferromagnet 34, the nonmagnet 33, the ferromagnet 32, and the nonmagnet 31 are stacked in this order, from the side of the word line WL (the interconnect layer 22) toward the side of the bit line BL (the interconnect layer 30).

The magnetoresistance effect element MTJ functions as, for example, a perpendicular-magnetization type magnetoresistance effect element in which the magnetization direction of a magnet constituting the magnetoresistance effect element MTJ is perpendicular to the film surface (in the Z direction in the example of FIG. 5). The magnetoresistance effect element MTJ may further include unillustrated layers between the layers 31-38.

The nonmagnet 31 is a nonmagnetic conductor, and functions as an electrode for improving electrical connectivity with the selector SEL (the element 24). The nonmagnet 31 contains, for example, a high-melting-point metal. The high-melting-point metal is a material having a melting point higher than that of, for example, iron (Fe) and cobalt (Co), and includes at least one element selected from zirconium (Zr), hafnium (Hf), tungsten (W), chromium (Cr), molybdenum (Mo), niobium (Nb), titanium (Ti), tantalum (Ta), vanadium (V), ruthenium (Ru), and platinum (Pt).

The ferromagnet 32 has ferromagnetic properties, and has an axis of easy magnetization in a direction perpendicular to the film surface. The magnetization direction of the ferromagnet 32 is fixed; in the example of FIG. 5, the magnetization direction is oriented to the ferromagnet 34. In this description, the “magnetization direction” being “fixed” means that the magnetization direction is not changed even by a current (spin torque) large enough to reverse the magnetization direction of the ferromagnet 36 (the storage layer SL). The ferromagnet 32 includes at least one alloy selected from, for example, cobalt platinum (CoPt), cobalt nickel (CoNi), and cobalt palladium (CoPd). The ferromagnet 32 may be a multi-layered body including a plurality of layers. In this case, the ferromagnet 32 may include, for example, at least one multilayer film selected from a multilayer film of cobalt (Co) and platinum (Pt), a multilayer film of cobalt (Co) and nickel (Ni), and a multilayer film of cobalt (Co) and palladium (Pd).

The nonmagnet 33 is provided between the ferromagnet 32 (the shift cancelling layer SCL) and the ferromagnet 34 (the reference layer RL). The nonmagnet 33 is a non-magnetic conductor, and contains at least one element selected from, for example, ruthenium (Ru), osmium (Os), iridium (Ir), vanadium (V), and chromium (Cr).

The ferromagnet 34 has ferromagnetic properties, and has an axis of easy magnetization in a direction perpendicular to the film surface. The magnetization direction of the ferromagnet 34 is fixed, and in the example of FIG. 5, oriented to the ferromagnet 32. The ferromagnet 34 contains, for example, at least one of iron (Fe), cobalt (Co), and nickel (Ni). The ferromagnet 34 may further contain boron (B). More specifically, the ferromagnet 34 may contain, for example, iron cobalt boron (FeCoB) or iron boron (FeB), and have a body-centered crystal structure.

The ferromagnet 34 may be a multi-layered body including multiple films, although not illustrated in FIG. 5. Specifically, the multi-layered body constituting the ferromagnet 34 may be, for example, a structure including a layer containing iron cobalt boron (FeCoB) or iron boron (FeB) as an interface layer with the nonmagnet 35, and including an additional ferromagnet stacked between the interface layer and the nonmagnet 33 via a nonmagnetic conductor. The non-magnetic conductor in the multi-layered body constituting the ferromagnet 34 may contain, for example, at least one metal selected from tantalum (Ta), hafnium (Hf), tungsten (W), zirconium (Zr), molybdenum (Mo), niobium (Nb), and titanium (Ti). The additional ferromagnet in the multi-layered body constituting the ferromagnet 34 may include at least one multilayer film selected from, for example, a multilayer film of cobalt (Co) and platinum (Pt), a multilayer film of cobalt (Co) and nickel (Ni), and a multilayer film of cobalt (Co) and palladium (Pd).

The ferromagnets 32 and 34 are coupled in an anti-ferromagnetic manner by the nonmagnet 33. In other words, the ferromagnets 32 and 34 are coupled in a manner in which they have mutually-antiparallel magnetization directions. Accordingly, the magnetization directions of the ferromagnets 32 and 34 are opposite to each other in the example of FIG. 5. Such a bonding structure of the ferromagnet 32, non-magnet 33, and ferromagnet 34 as described above is called a Synthetic Anti-Ferromagnetic (SAF) structure. This allows the ferromagnet 32 to compensate for the influence of a stray field of the ferromagnet 34 on the magnetization direction of the ferromagnet 36. This suppresses asymmetry from occurring in the ease of rotation of the magnetization direction of the ferromagnet 36, due to, e.g., a stray field of the ferromagnet 34 (that is, suppresses the ease of reversal of the magnetization direction of the ferromagnet 36 from differing between the case of reversing from one side to the other and the case of reversing in the opposite direction).

The nonmagnet 35 is a non-magnetic insulator, and contains, for example, magnesium oxide (MgO). The nonmagnet 35 has an NaCl crystal structure with its film surface oriented in a (001) plane, and functions as a seed material to be a nucleus for growth of a crystalline film from an interface with the ferromagnet 36 during a crystallization process of the ferromagnet 36. The nonmagnet 35 is arranged between the ferromagnet 34 and the ferromagnet 36, and constitutes a magnetic tunnel junction together with the two ferromagnets.

The ferromagnet 36 has ferromagnetic properties, and has an axis of easy magnetization in a direction perpendicular to a film surface. In other words, the ferromagnet 36 has a magnetization directed toward either the bit lines BL or the word lines WL in the Z direction. The ferromagnet 36 contains at least one of iron (Fe), cobalt (Co), and nickel (Ni). The ferromagnet 36 further contains boron (B). More specifically, the ferromagnet 36 may contain, for example, iron cobalt boron (FeCoB) or iron boron (FeB), and have a body-centered crystal structure.

The nonmagnet 37 has a function of suppressing the damping coefficient of the ferromagnet 36 from increasing, and reducing a write current. The nonmagnet 37 contains at least one nitride or oxide selected from, for example, magnesium oxide (MgO), magnesium nitride (MgN), zirconium nitride (ZrN), niobium nitride (NbN), silicon nitride (SiN), aluminum nitride (AlN), hafnium nitride (HfN), tantalum nitride (TaN), tungsten nitride (WN), chromium nitride (CrN), molybdenum nitride (MoN), titanium nitride (TiN), and vanadium nitride (VN). The nonmagnet 37 may be a mixture of any of these nitrides and oxides. Specifically, the nonmagnet 37 is not limited to a binary compound consisting of two different elements, and may be a ternary compound consisting of three different elements, such as titanium aluminum nitride (AlTiN).

The nonmagnet 38 is a nonmagnetic conductor, and functions as a top electrode that enhances electrical connectivity between the upper end of the magnetoresistance effect element MTJ and the bit line BL. The nonmagnet 38 contains at least one element or a compound selected from, for example, tungsten (W), tantalum (Ta), tantalum nitride (TaN), titanium (Ti), and titanium nitride (TiN).

In the present embodiment, a write current is allowed to flow through the magnetoresistance effect element MTJ, and a spin torque is injected into the storage layer SL. A spin injection write technique, in which the magnetization direction of the storage layer SL is controlled by the injected spin torque, is adopted. The magnetoresistance effect element MTJ can take one of a low-resistance state and a high-resistance state, depending on whether the magnetization directions of the storage layer SL and the reference layer RL are parallel or antiparallel.

When a write current Ic0 of a magnitude is allowed to flow through the magnetoresistance effect element MTJ in the direction of an arrow A1 in FIG. 5, namely, the direction from the storage layer SL toward the reference layer RL, the relative relationship between the magnetization direction of the storage layer SL and the magnetization direction of the reference layer RL becomes parallel. In this parallel state, the magnetoresistance effect element MTJ has the least resistance value, and the magnetoresistance effect element MTJ is set to a low-resistance state. This low-resistance state is called “parallel (P) state”, and is defined as, for example, the state of data “0”.

When a write current Ic1 of a magnitude greater than that of the write current Ic0 is allowed to flow through the magnetoresistance effect element MTJ in the direction of an arrow A2 in FIG. 5, namely, the direction from the reference layer RL toward the storage layer SL (opposite to the arrow A1), the relative relationship between the magnetization directions of the storage layer SL and the reference layer RL becomes antiparallel. In this antiparallel state, the magnetoresistance effect element MTJ has the highest resistance value, and the magnetoresistance effect element MTJ is set to a high-resistance state. This high-resistance state is called “anti-parallel (AP) state”, and is defined as, for example, the state of data “1”.

A description will be given below in accordance with the above-described definition of data; however, the definition of data “1” and data “0” is not limited thereto. For example, the P state may be defined as data “1”, and the AP state may be defined as data “0”.

1.2 Method for Manufacturing Memory Cell Array

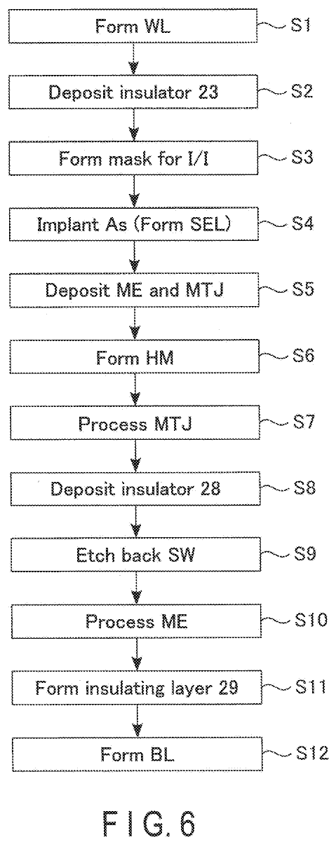

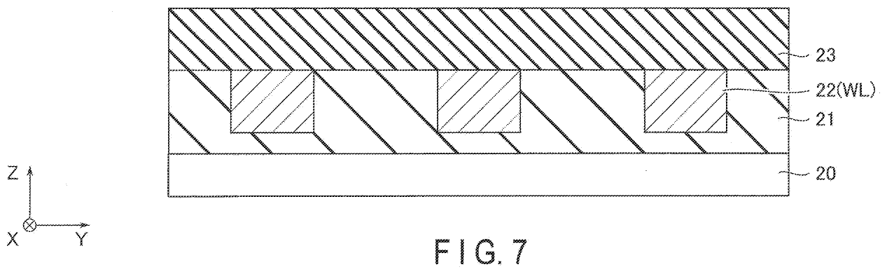

Next, an example of a method for manufacturing the memory cell array 10 will be explained with reference to FIG. 6 to FIG. 14. FIG. 6 is a flowchart showing a method for manufacturing the memory cell array 10. FIG. 7 to FIG. 14 are cross-sectional views of the memory cell array 10 to explain the method for manufacturing the memory cell array 10. In the explanation below, details of the stacked structure constituting the element 26 (the magnetoresistance effect element MTJ) are omitted.

As illustrated in FIG. 7, the insulating layer 21 is formed on the upper surface of the semiconductor substrate 20. Next, the interconnect layers 22 functioning as the word lines WL are formed in the insulating layer 21 (step S1 in FIG. 6; Form WL). The interconnect layers 22 may be trench interconnects obtained by forming trench patterns on a top portion of the insulating layer 21 and thereafter filling the insides of the trench patterns with a conductive material. Alternatively, the interconnect layers 22 may be obtained by depositing a conductive material on the insulating layer 21 and thereafter processing the conductive material. In this case, after the interconnect layers 22 are formed, the insulating layer 21 is formed to fill a space between the interconnect layers 22.

On the upper surfaces of the insulating layer 21 and the interconnect layers 22, the insulating layer 23 is deposited by, for example, Chemical Vapor Deposition (CVD) (step S2 in FIG. 6; Deposit insulator 23).

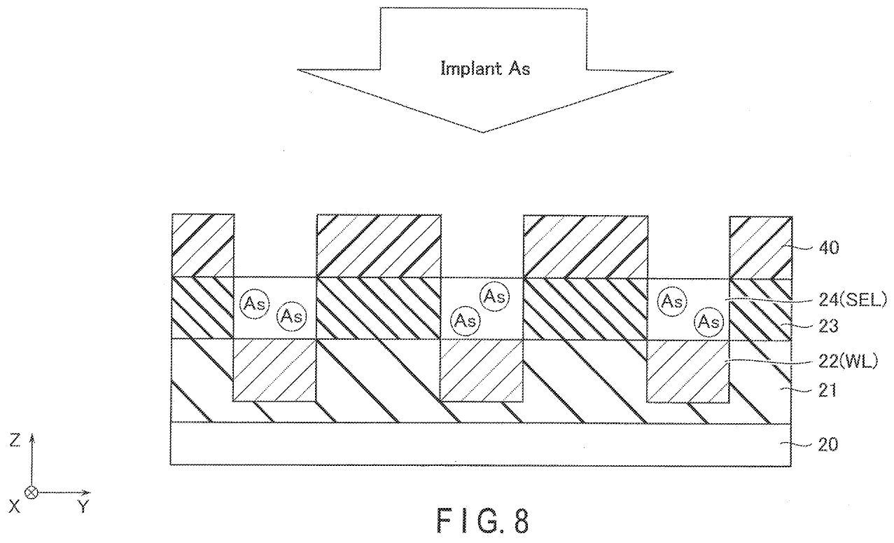

As illustrated in FIG. 8, a resist mask 40 for ion implantation (I/I) is formed on the upper surface of the insulating layer 23, using photolithography (step S3 in FIG. 6: Form mask for I/I). The resist mask 40 is opened at areas corresponding to the selectors SEL (the elements 24). In this state, ion implantation using, for example, As as the dopant is carried out. After the ion implantation, the resist mask 40 is removed by, for example, O₂ ashing. Next, a heat treatment for activating As is performed. As a result, the elements 24 are formed in the areas of the insulating layer 23 that have been doped with As (step S4 in FIG. 6: Implant As (Form SEL)).

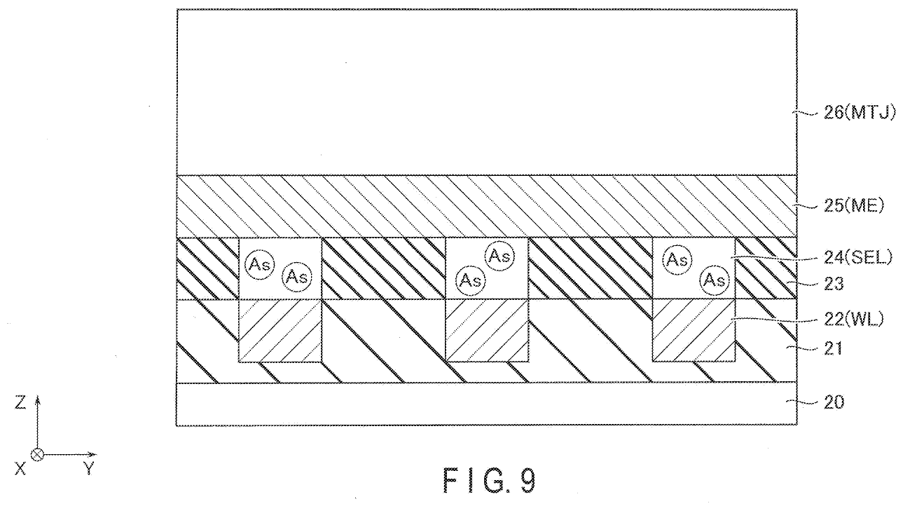

As illustrated in FIG. 9, the conductor 25 and the stacked film corresponding to the elements 26 (namely, the nonmagnet 31, the ferromagnet 32, the nonmagnet 33, the ferromagnet 34, the nonmagnet 35, the ferromagnet 36, the nonmagnet 37, and the nonmagnet 38) are sequentially deposited by CVD, sputtering, or the like (step S5 in FIG. 6: Deposit ME and MTJ).

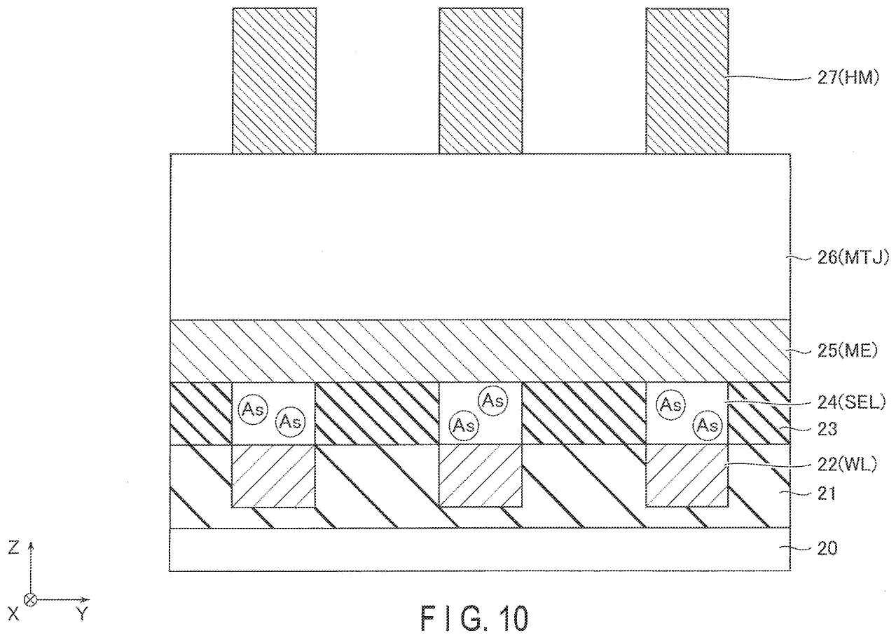

As illustrated in FIG. 10, the hard masks 27 are formed on the stacked film corresponding to the elements 26 (step S6 in FIG. 6: Form HM).

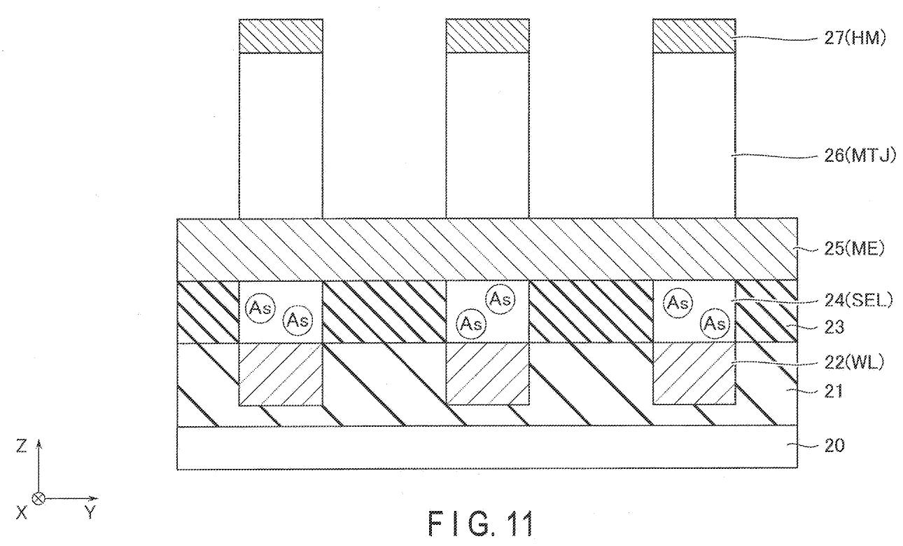

As illustrated in FIG. 11, the stacked film corresponding to the elements 26 is processed by, for example, ion beam etching (IBE) using the hard masks 27 as masks, thereby forming the elements 26. Thus, the magnetoresistance effect elements MTJ are formed (step S7 in FIG. 6: Process MTJ).

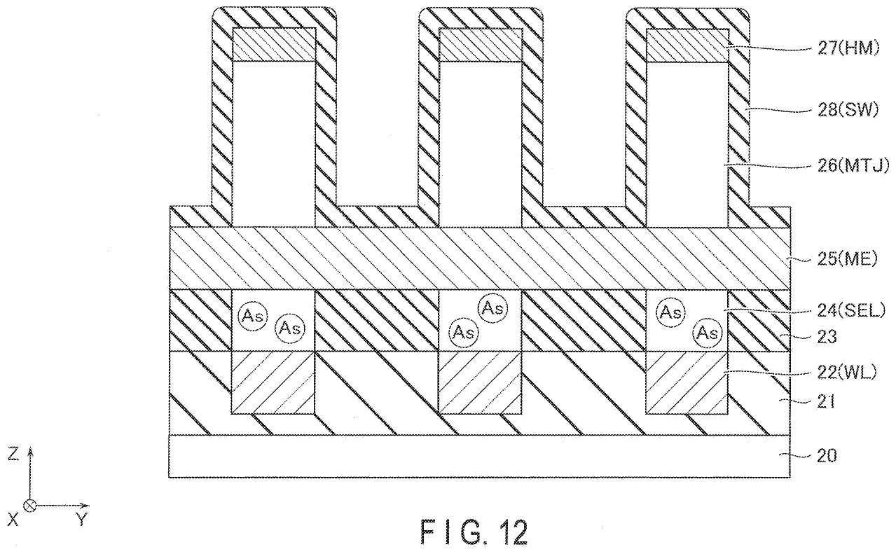

As illustrated in FIG. 12, the insulator 28 is deposited to cover the upper surface of the conductor 25, the side surfaces of the elements 26, and the upper and side surfaces of the hard masks 27 by, for example, CVD (step S8 in FIG. 6: Deposit insulator 28).

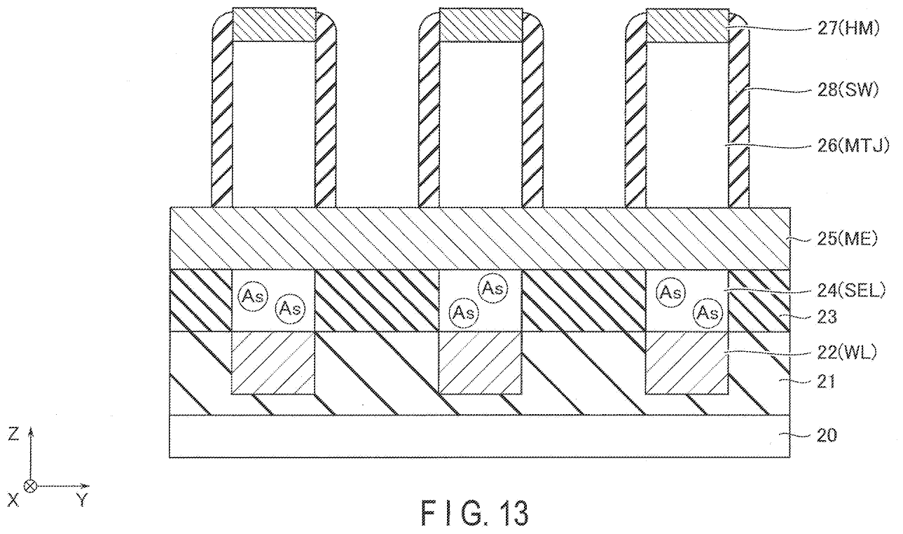

As illustrated in FIG. 13, the insulator 28 on the upper surface of the conductor 25 and the upper surfaces of the hard masks 27 is removed through etching back by, for example, Reactive Ion Etching (RIE) (step S9 in FIG. 6: Etch back SW). As a result, the side walls SW formed of the insulator 28 are formed on the elements 26 and the hard masks 27.

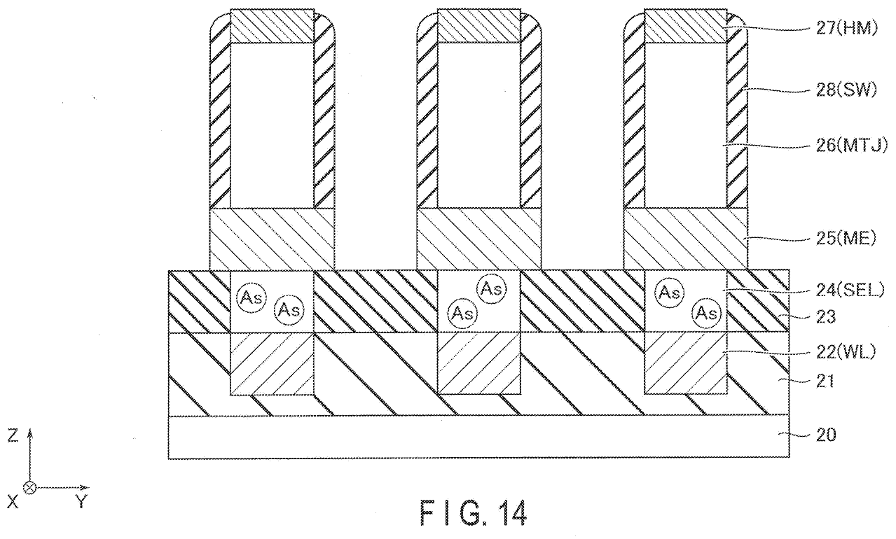

As illustrated in FIG. 14, the conductor 25 is processed by, for example, RIE, using the hard masks 27 and the insulator 28 as masks (step S10 in FIG. 6: Process ME). As a result, the middle electrodes ME are formed.

As illustrated in FIG. 3, the insulating layer 29 is formed to fill the spaces between the conductors 25 and between the insulators 28 (step S11 in FIG. 6: Form insulating layer 29). Thereafter, the interconnect layer 30 is formed on the upper surfaces of the hard masks 27 (step S12 in FIG. 6: Form BL).

1.3 Advantages of Embodiment

The configuration of the present embodiment can lower the difficulty level of processing magnetoresistance effect elements MTJ. Such an advantage will be explained in detail below.

In a structure in which the middle electrode ME and the magnetoresistance effect element MTJ are formed on the upper surface of the selector SEL, the magnetoresistance effect element MTJ, the middle electrode ME, and the selector SEL may be processed using the hard mask 27 on the upper surface of the magnetoresistance effect element MTJ as a mask. Therefore, the hard mask 27 is formed to be relatively thick so as not to be lost while the materials of these components are processed. If the hard mask 27 is thick, the aspect ratio in processing the magnetoresistance effect element MTJ is increased. Therefore, high requirements are placed on the shape of the magnetoresistance effect element MTJ (a remaining film of the hard mask 27, an angle of the side surface of the magnetoresistance effect element MTJ, etc.) to process the middle electrode ME and the selector SEL. Thus, the difficulty level of processing the magnetoresistance effect elements MTJ is increased.

For example, if the side surfaces of the magnetoresistance effect element MTJ, the middle electrode ME, and the selector SEL are tapered, the distance between the adjacent selectors SEL is shorter than the distance between the adjacent middle electrodes ME. In this case, a leak current or interference due to capacity coupling may be liable to occur between the adjacent selectors SEL. Accordingly, it is highly possible that a malfunction may occur in a write operation and a read operation. Furthermore, to suppress the interference between the adjacent selectors SEL, the cell density of the memory cells MC on the XY plane may not be increased.

In contrast, in the configuration according to the present embodiment, the selector SEL can be formed before the middle electrode ME and the magnetoresistance effect element MTJ are formed. In other words, the selector SEL can be formed without using the hard mask 27. Therefore, the hard mask 27 can be minimized in thickness yet still not to be lost while the magnetoresistance effect element MTJ and the middle electrode ME are being processed. Therefore, it is possible to suppress the increase in difficulty level of processing the magnetoresistance effect elements MTJ due to the increase in thickness of the hard mask 27.

Furthermore, in the configuration according to the present embodiment, the diameter of the upper surface of the selector SEL can be smaller than the diameter of the lower surface of the middle electrode ME. In other words, the area of the upper surface of the selector SEL can be smaller than the area of the lower surface of the middle electrode ME. Therefore, the distance between the adjacent selectors SEL can be longer than the distance between the adjacent middle electrodes ME. Accordingly, the interference between the adjacent selectors SEL can be suppressed. Thus, the interference between the adjacent magnetoresistance effect elements MTJ can be suppressed. It is thus possible to suppress the occurrence of malfunctions and improve the reliability of the magnetic memory device.

Moreover, in the configuration according to the present embodiment, the increase in difficulty level of processing the magnetoresistance effect elements MTJ can be suppressed, and the interference between the adjacent magnetoresistance effect elements MTJ can be suppressed. Therefore, the cell density of the memory cells MC can be increased, to achieve high integration of the magnetic memory device.

### 2. Second Embodiment

A second embodiment will now be explained. In the explanation of the second embodiment below, a method for manufacturing a memory cell MC is different from the first embodiment. Hereinafter, differences from the first embodiment will be mainly explained.

2.1 Cross-Sectional Structure of Memory Cell Array

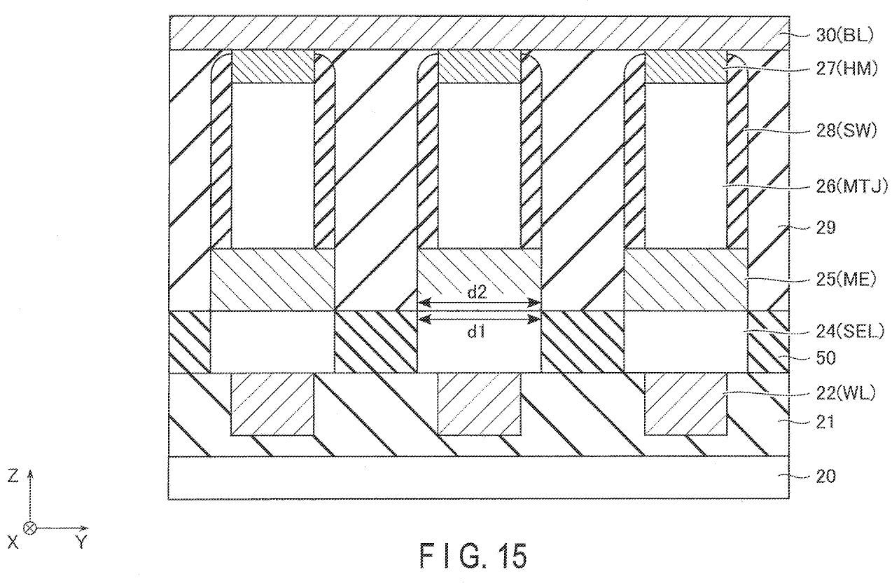

First, an example of a cross-sectional structure of a memory cell array 10 will be explained with reference to FIG. 15. FIG. 15 shows an example of a cross-sectional view for explaining the configuration of the memory cell array.

As illustrated in FIG. 15, according to the present embodiment, an insulating layer 50 is provided on an upper surface of the insulating layer 21. The insulating layer 50 is a layer in which a dopant (for example, As) of the selector SEL and a dopant to inactivate the dopant of the selector SEL are implanted into the insulating layer 23 of the first embodiment explained above. In the following, a case will be explained in which boron (B) is used as the dopant to inactivate As, which is the dopant of the selector SEL. For example, to inactivate As, it is preferable that the concentration of B is higher than the concentration of As, and that the concentration of B does not allow to precipitate B on the surface of the insulating layer 50, so as not to increase the roughness of the surface of the insulating layer 50. In other words, the concentration of B may be such that the adjacent elements 24 (the selector SEL) can be electrically isolated from each other.

The insulating layer 50 of the present embodiment can be formed by implanting B into a layer corresponding to the element 24. Thus, the element 24 and the insulating layer 50 are formed without a process of dry etching or the like. Therefore, an interface between the insulating layer 50 and the element 24 cannot be observed with, for example, a TEM. However, the element 50 can be recognized by measuring a distribution of the dopant by an EDX analysis, or the like, with the TEM.

In the present embodiment, B is ion-implanted into an area corresponding to the insulating layer 50 using the hard mask 27, the insulator 28, and the conductor 25 as a mask. A major axis d1 of the upper surface of the element 24 and a major axis d2 of the lower surface of the conductor 25 satisfy the relation of d1≤d2, depending on conditions of the ion implantation (an incidence angle of ion or the like), an influence of diffusion of B due to a heat treatment, etc.

2.2 Method for Manufacturing Memory Cell Array

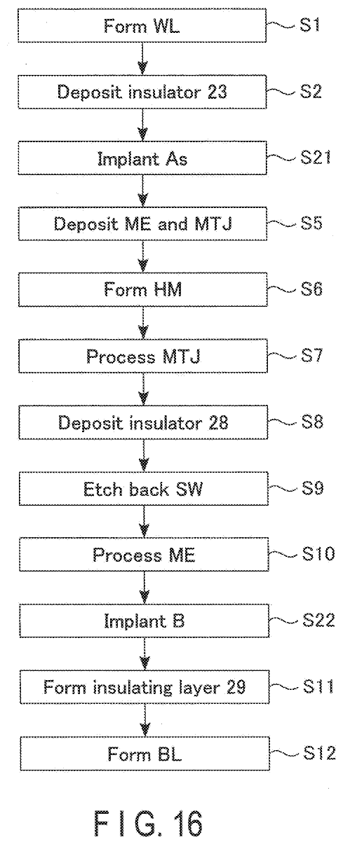

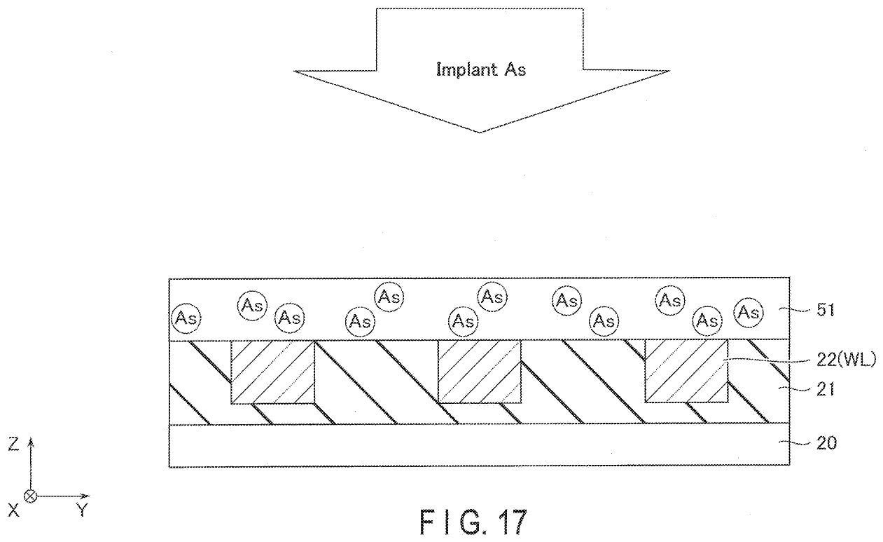

Next, an example of a method for manufacturing a memory cell array 10 will be explained with reference to FIG. 16 to FIG. 19. FIG. 16 is a flowchart showing a method for manufacturing the memory cell array 10. FIG. 17 to FIG. 19 are cross-sectional views of the memory cell array 10 to explain the method for manufacturing the memory cell array 10. In the explanation below, details of the stacked structure constituting the element 26 (the magnetoresistance effect element MTJ) are omitted.

As shown in FIG. 16, the process from the start to the deposition of an insulating layer 23 (steps S1 and S2) are equivalent to those in the first embodiment.

As illustrated in FIG. 17, after the insulating layer 23 is deposited, ion implantation using As as a dopant is performed (step S21 in FIG. 16: Implant As). Then, a heat treatment to activate As is performed. As a result, a layer 51 corresponding to the elements 24 are formed on the upper surfaces of the insulating layer 21 and the interconnect layers 22. As may be diffused to a surface region of the insulating layer 21, namely, to a portion below the upper surface of the interconnect layers 22 (near the semiconductor substrate 20).

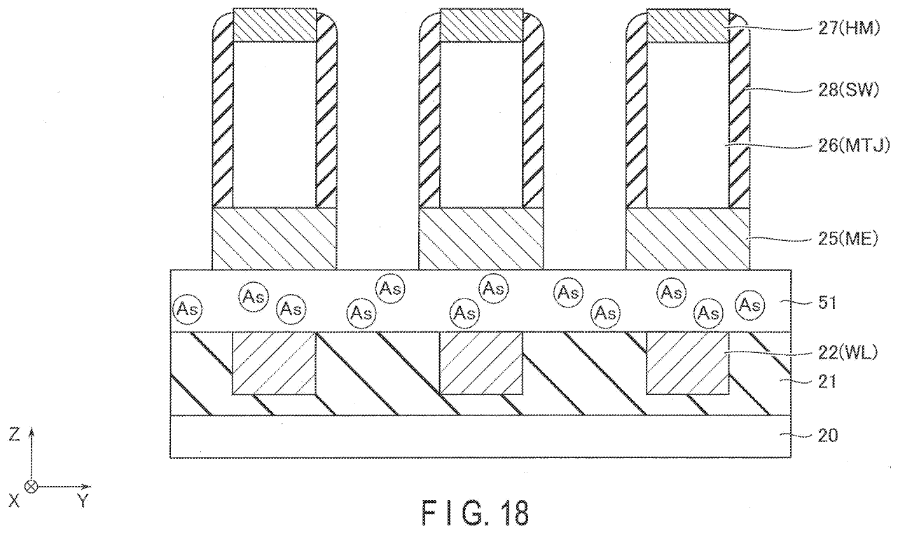

As illustrated in FIG. 18, the conductors 25, the elements 26, the hard masks 27, and the insulators 28 are formed in the same manner as in steps S5 to S10 in FIG. 6 and as illustrated in FIG. 9 to FIG. 14 of the first embodiment. Thus, the magnetoresistance effect elements MTJ and the middle electrode ME are formed.

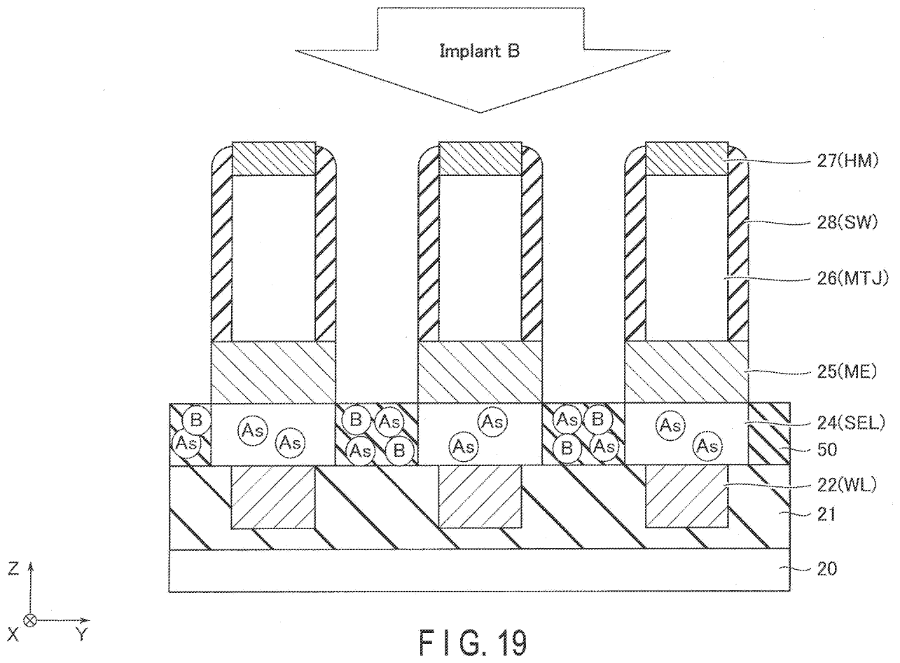

As illustrated in FIG. 19, after the conductors 25 are processed, ion implantation using B as the dopant is performed (step S22 in FIG. 16: Implant B). As a result, B is implanted into regions of the layer 51 that are not masked with the hard masks 27, the insulators 28, and the conductors 25. Next, a heat treatment to activate B (to inactivate As) is performed. As a result, the insulating layers 50 are formed in the regions of the layer 51 in which B is implanted, and the elements 24 are formed in the regions in which B is not implanted. To isolate the elements 24 from one another, the concentration profile of B in the depth direction (the Z direction) after the heat treatment is preferably deeper than the concentration profile of As. In other words, it is preferable that B diffuses deeper than As to a portion near the semiconductor substrate 20. The profiles of As and B can be measured by an EDX analysis or the like with the TEM.

Thereafter, the insulating layer 29 and the interconnect layer 30 are formed in the same manner as in steps S11 and S12 shown in FIG. 6 of the first embodiment.

2.3 Advantages of Embodiment

The configuration of the present embodiment can attain advantages similar to those of the first embodiment.

In addition, according to the configuration of the present embodiment, since a resist mask is unnecessary when implanting As, it is possible to avoid the need for an additional process of a photolithography step.

### 3. Modification, etc.

The above-described embodiments are merely examples, and can be modified in various manners.

For example, in the embodiments described above, the magnetoresistance effect element MTJ has a top-free structure in which the storage layer SL is provided above the reference layer RL. However, the embodiments are not limited thereto. For example, the magnetoresistance effect element MTJ may have a bottom-free structure in which the storage layer SL is provided below the reference layer RL.

Furthermore, in the memory cell array 10 of the embodiments described above, all memory cells MC are provided in the same layer. However, the embodiments are not limited thereto. A plurality of memory cells MC may be stacked in the Z direction.

In the embodiments described above, the middle electrodes ME and the magnetoresistance effect elements MTJ are provided on the upper surfaces of the selectors SEL. However, the embodiments are not limited thereto. For example, the middle electrodes ME and the selectors SEL may be provided on the upper surfaces of the magnetoresistance effect elements.

The method for manufacturing the middle electrodes ME and the magnetoresistance effect elements MTJ is not limited to that of the embodiments described above. As long as the selectors SEL are formed in the same manner as the manufacturing method of the embodiment described above, the middle electrodes ME and the magnetoresistance effect elements MTJ may be formed by any method.

While several embodiments have been described, these embodiments have been presented by way of example and are not intended to limit the scope of the invention. These novel embodiments may be realized in various other forms, and various omissions, replacements, and changes can be made without departing from the gist of the invention. Such embodiments and modifications are included in the scope and gist of the invention, and are included in the scope of the invention described in the claims and their equivalents.

1. A magnetic memory device comprising:
a first interconnect extending in a first direction;
a switching element provided on the first interconnect;
a conductor provided on the switching element;
a magnetoresistance effect element provided on the conductor; and
an insulating layer provided in a layer in which the switching element is provided,
wherein an area of a first principal surface of the switching element that faces the conductor is smaller than that of a second principal surface of the conductor that faces the switching element.

2. The magnetic memory device according to claim 1, wherein a major axis of the first principal surface is shorter than that of the second principal surface.

3. The magnetic memory device according to claim 1, wherein:
the switching element contains silicon and arsenic; and
the insulating layer contains silicon and contains no arsenic.

4. The magnetic memory device according to claim 1, further comprising:
a hard mask provided on the magnetoresistance effect element; and
a second interconnect provided on the hard mask and extending in a second direction intersecting the first direction.

5. The magnetic memory device according to claim 1, wherein the magnetoresistance effect element includes a reference layer, a storage layer, and a tunnel barrier layer interposed between the reference layer and the storage layer.

6. A magnetic memory device comprising:
a first interconnect extending in a first direction;
a switching element provided on the first interconnect;
a conductor provided on the switching element;
a magnetoresistance effect element provided on the conductor; and
an insulating layer provided in a layer in which the switching element is provided, and containing arsenic and boron.

7. The magnetic memory device according to claim 6, wherein the switching element contains arsenic and contains no boron.

8. The magnetic memory device according to claim 6, wherein a major axis of a first principal surface of the switching element that faces the conductor is equal to or shorter than that of a second principal surface of the conductor that faces the switching element.

9. The magnetic memory device according to claim 6, further comprising:
a hard mask provided on the magnetoresistance effect element; and
a second interconnect provided on the magnetoresistance effect element and the hard mask.

10. The magnetic memory device according to claim 6, wherein the magnetoresistance effect element includes a reference layer, a storage layer, and a tunnel barrier layer interposed between the reference layer and the storage layer.

11. A method for manufacturing a magnetic memory device comprising:
forming a first interconnect extending in a first direction in a first insulating layer;
forming a second insulating layer on the first insulating layer and on the first interconnect;
forming, on the second insulating layer, a resist mask corresponding to a switching element to be provided on the first interconnect;
implanting arsenic in a region of the second insulating layer where the resist mask is not formed, thereby forming the switching element; and
forming a conductor and a magnetoresistance effect element on the switching element.

12. The method according to claim 11, wherein the forming the conductor and the magnetoresistance effect element includes:
depositing the conductor and a stacked film corresponding to the magnetoresistance effect element;
forming a hard mask on the stacked film;
processing the stacked film using the hard mask as a mask, thereby forming the magnetoresistance effect element;
forming an insulator on side surfaces of the hard mask and the magnetoresistance effect element; and
processing the conductor using the hard mask and the insulator as a mask.

13. The method according to claim 12, wherein the stacked film includes a first ferromagnet, a second ferromagnet, and a nonmagnet interposed between the first ferromagnet and the second ferromagnet.

14. The method according to claim 12, further comprising forming, on the hard mask, a second interconnect extending in a second direction intersecting the first direction.
